(19) United States
(12) Patent Application Publication
(10) Pub. No.: US 2025/0275152 A1
(43) Pub. Date: Aug. 28, 2025

(54) FERROELECTRIC CAPACITOR RESISTING FATIGUE, FERROELECTRIC STORAGE CIRCUIT, AND FERROELECTRIC MEMORY THEREOF

(71) Applicant: UNIVERSITY OF SCIENCE AND TECHNOLOGY OF CHINA, Hefei (CN)

(72) Inventors: Guangwei Xu, Hefei (CN); Xinyi Tang, Hefei (CN); Di Lv, Hefei (CN); Weiping Bai, Hefei (CN); Shibing Long, Hefei (CN)

(21) Appl. No.: 19/201,952

(22) Filed: May 8, 2025

Related U.S. Application Data
(63) Continuation of application No. PCT/CN2024/133894, filed on Nov. 22, 2024.

(30) Foreign Application Priority Data
Nov. 23, 2023 (CN) 202311573937.3

(51) Int. Cl. H10B 53/30

(52) U.S. Cl. CPC H10B 53/30

(57) ABSTRACT

A ferroelectric capacitor resisting fatigue, ferroelectric storage circuit, and ferroelectric memory thereof, the capacitor includes an upper electrode layer, a top electrode layer, a non-crystalline protective layer, a ferroelectric dielectric layer, and a bottom electrode layer in sequential order from top to bottom. The ferroelectric dielectric layer consists essentially of a fluorite-structure material selected from the group consisting of ZrO2, HfO2 and HfxZr1-xO2. The non-crystalline protective layer comprises a fluorite-structure base material and is doped with a predetermined amount of at least one element selected from the group consisting of Al, Si, La, Y, Nb, Ce, and Er, whereby the non-crystalline protective layer attains a non-crystalline state. The non-crystalline protective layer has a thickness ranging from 10% to 40% of a thickness of the ferroelectric dielectric layer. The capacitor exhibits enhanced fatigue resistance, preserved ferroelectric properties, reduced leakage current, simplified manufacturing processes, lower production costs, improved device reliability.

### FIELD OF THE INVENTION

The present invention relates to the technical field of memory devices, and more particularly to a ferroelectric capacitor resisting fatigue, a ferroelectric storage circuit incorporating said capacitor, and a ferroelectric memory including said circuit.

### BACKGROUND OF THE INVENTION

Memory devices are critical in modern computing systems, but conventional technologies like DRAM and NAND Flash face limitations under Moore's Law scaling, resulting in rising costs and stagnant performance. Emerging solutions include ferroelectric memory (FeFET) based on hafnium zirconium oxide (HZO) thin films, which exhibit fast read/write speeds, non-volatility, low power consumption, and CMOS compatibility. Compared to perovskite-based materials (e.g., PZT), HZO exhibits superior scalability (retaining ferroelectricity below 10 nm thickness), a favorable coercive field (E_{c}) for reduced switching voltage, and full CMOS process integration, making it suitable for FeFET and FRAM applications.

Data writing in HZO-based capacitors requires an operational field (E_{work}) exceeding 2×E_{c} to address device-level E_{c} variations and fatigue-induced E_{c} shifts. However, HZO's high E_{c} forces E_{work} near breakdown voltage, causing reliability degradation and limiting commercialization. Prior solutions—defect engineering, phase control, and Al₂O₃ capping layers—partially mitigate fatigue but introduce trade-offs: Al₂O₃ layers increase equivalent oxide thickness, degrade ferroelectricity at greater thicknesses, extend ALD deposition time, and create interface defect risks, ultimately hindering scalability and mass production.

### SUMMARY OF THE INVENTION

Therefore, the object of the present invention is to provide a ferroelectric capacitor resisting fatigue exhibiting enhanced fatigue resistance, preserved ferroelectric properties, reduced leakage current, simplified manufacturing processes, lower production costs, and improved device reliability.

A further object of the present invention is to provide a ferroelectric storage circuit incorporating said ferroelectric capacitor resisting fatigue.

Another object of the present invention is to provide a ferroelectric memory including said ferroelectric storage circuit.

The present invention provides a ferroelectric capacitor resisting fatigue including, in sequential order from top to bottom: an upper electrode layer, a top electrode layer, a non-crystalline protective layer, a ferroelectric dielectric layer, and a bottom electrode layer; wherein, the ferroelectric dielectric layer consists essentially of a fluorite-structure material selected from the group consisting of ZrO₂, HfO₂ and HfₓZr₁₋ₓO₂; the non-crystalline protective layer includes the same fluorite-structure base material as the ferroelectric dielectric layer and is doped with a predetermined amount of at least one element selected from the group consisting of Al, Si, La, Y, Nb, Ce, and Er, whereby the non-crystalline protective layer attains a non-crystalline state; the non-crystalline protective layer has a thickness ranging from 10% to 40% of a thickness of the ferroelectric dielectric layer.

The present invention also provides a ferroelectric storage circuit including a silicon substrate and a circuit structure disposed on the silicon substrate and including the ferroelectric capacitor resisting fatigue.

In the circuit of the present invention, the circuit further includes at least one ferroelectric field-effect transistor (FeFET) and at least one ferroelectric random-access memory (FRAM).

In the capacitor or circuit of the present invention, the non-crystalline protective layer is formed by ALD, and the dopant material and the ferroelectric dielectric layer material are alternately deposited in a predetermined sequence and ratio to achieve the predetermined thickness of the non-crystalline protective layer.

In the capacitor or circuit of the present invention, the non-crystalline protective layer is formed by: depositing 2 to 3 cycles of the dopant material directly on an underlying base layer; depositing 8 cycles of the ferroelectric dielectric layer material; and depositing 2 to 3 cycles of the dopant material.

In the capacitor or circuit of the present invention, both the top electrode layer and the bottom electrode layer include TiN and are formed by PEALD.

In the capacitor or circuit of the present invention, the top electrode layer has a thickness of 10 nm to 20 nm, the bottom electrode layer has a thickness of 5 nm to 10 nm.

In the capacitor or circuit of the present invention, the upper electrode layer includes SiGe and is formed by electron beam evaporation, and the upper electrode layer has a thickness of 270 nm to 300 nm.

In the capacitor or circuit of the present invention, the ferroelectric dielectric layer is formed by ALD and has a thickness of 5 nm.

The present invention also provides a ferroelectric memory including a large-scale integrated circuit formed by a plurality of unit circuits, each unit circuit being the ferroelectric storage circuit according to the ferroelectric storage circuit.

In the memory of the present invention, the memory is fabricated by a method including: (a) cleaning a silicon substrate and depositing a continuous layer of TiN as the bottom electrode on the silicon substrate using PEALD; (b) forming a continuous film of the ferroelectric dielectric layer on the TiN bottom electrode using ALD; (c) depositing 2 to 3 cycles of a dopant material, then 8 cycles of the ferroelectric dielectric layer material, and finally 2 to 3 cycles of the dopant material using ALD to form the non-crystalline protective layer; (d) depositing TiN as the top electrode layer on the non-crystalline protective layer using PEALD; (e) depositing a SiGe layer as the upper electrode layer on the top electrode layer using electron beam evaporation; and (f) patterning the multilayer structure using photolithography and etching with an inductively coupled plasma etcher to form a metal-ferroelectric-metal (MFM) circuit structure.

In the memory of the present invention, the non-crystalline protective layer is formed by ALD, and the dopant material and the ferroelectric dielectric layer material are alternately deposited in a predetermined sequence and ratio to achieve the predetermined thickness of the non-crystalline protective layer.

In the memory of the present invention, the non-crystalline protective layer is formed by: depositing 2 to 3 cycles of the dopant material directly on an underlying base layer; depositing 8 cycles of the ferroelectric dielectric layer material; and depositing 2 to 3 cycles of the dopant material.

In the memory of the present invention, both the top electrode layer and the bottom electrode layer include TiN and are formed by PEALD; the top electrode layer has a thickness of 10 nm to 20 nm, the bottom electrode layer has a thickness of 5 nm to 10 nm; the upper electrode layer includes SiGe and is formed by electron beam evaporation, and the upper electrode layer has a thickness of 270 nm to 300 nm; the ferroelectric dielectric layer is formed by ALD and has a thickness of 5 nm.

Solution of the present invention, for solving the above problem, a capacitor is provided which has a novel thin-film structure, and an HZO film is doped with at least one element selected from the group consisting of Al, Si, La, Y, Nb, Ce, and Er to form a non-crystalline protective layer of controlled thickness within a specific range. This non-crystalline protective layer prevents the formation of vertical grain boundaries in conventional ferroelectric capacitors, blocks oxygen vacancy migration, and suppresses conductive filament formation, thereby enhancing fatigue resistance. Furthermore, the non-crystalline protective layer introduces no additional interfaces, maintains stable ferroelectric properties, improves time-dependent dielectric breakdown performance, and reduces leakage current.

The invention relates to an improved HZO-based ferroelectric capacitor. The disclosed thin-film structure increases polarization switching cycles in FeFET devices, enhances fatigue characteristics, and ensures reliable data storage. From a manufacturing perspective, the solution requires only minor modifications to dielectric growth processes by adjusting ALD equipment recipes, making it compatible with existing production lines. The ferroelectric memory devices can be manufactured using conventional DRAM production lines without requiring new facility design or process development, enabling easy implementation while reducing production costs.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic diagram illustrating the thin-film structure of a ferroelectric capacitor resisting fatigue according to the first embodiment of the present invention.

FIG. 2 is a schematic diagram showing the state of a substrate prior to deposition in the fabrication method of the ferroelectric memory disclosed in the fourth embodiment.

FIG. 3 is a schematic diagram showing the state of the substrate after deposition of the bottom electrode layer in the fabrication method of the ferroelectric memory of the fourth embodiment.

FIG. 4 is a schematic diagram showing the state of the substrate after formation of the ferroelectric dielectric layer in the fabrication method of the ferroelectric memory of the fourth embodiment.

FIG. 5 is a schematic diagram showing the state of the substrate after formation of the non-crystalline protective layer in the fabrication method of the ferroelectric memory of the fourth embodiment.

FIG. 6 is a schematic diagram showing the state of the substrate after deposition of the top electrode layer in the fabrication method of the ferroelectric memory of the fourth embodiment.

FIG. 7 is a schematic diagram showing the state of the substrate after deposition of the upper electrode layer in the fabrication method of the ferroelectric memory of the fourth embodiment.

FIG. 8 is a schematic diagram showing the state of the ferroelectric memory after completion of photolithographic patterning in the fabrication method of the fourth embodiment.

FIG. 9 is a structural comparison diagram of three device configurations tested in the performance evaluation, including the experimental and control groups.

FIG. 10 is a plot of remnant polarization curves obtained from high-field cycling experiments performed on the three device samples in the performance evaluation.

FIG. 11 is a schematic diagram illustrating the mechanism underlying the enhanced fatigue resistance achieved by the technical solution of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

### Explanation of Technical Terms in the Invention:

Fluorite-structure: The term ‘fluorite-structure’ as used herein refers to a crystal structure adopted by hafnium-zirconium-oxygen (HZO)-based materials, characterized by a face-centered cubic lattice with oxygen vacancies stabilized within the matrix. The X ions occupy eight tetrahedral interstitial sites, while the M ions occupy regular sites in a face-centered cubic (FCC) lattice. In the present invention, the hafnium-zirconium-oxygen (HZO)-based ferroelectric dielectric layer adopts the fluorite structure.

Perovskite-structure: A perovskite is any material with a crystal structure following the formula ABX₃, where A and B are two cations (positively charged ions) of significantly different sizes, and X is an anion (negatively charged ion, typically oxygen) that bonds to both cations. Conventional ferroelectric capacitors employ perovskite-structured materials for their ferroelectric dielectric. In contrast, the innovative technology disclosed herein utilizes a fluorite-structured HZO-based system. The HZO-based ferroelectric material includes oxides of zirconium (Zr) and hafnium (Hf), including ZrO₂, HfO₂, or HfₓZr₁₋ₓO₂.

Non-crystalline Layer: In condensed matter physics and materials science, a non-crystalline solid (or non-crystalline solid) lacks long-range order in its atomic arrangement. In the present invention, the HZO-based ferroelectric dielectric material is doped with elements such as Al, La, Si, Y, Nb, Ce, or Er to induce a non-crystalline state, thereby forming a non-crystalline protective layer.

With technological advancements and device miniaturization, conventional perovskite-structured ferroelectric systems face critical limitations, including insufficient retention of ferroelectric properties in ultrathin films (<10 nm) and impractical coercive fields (˜0.1 MV/cm) for precise control. Emerging fluorite-structured HZO films have gradually replaced perovskite materials as the dielectric layer in ferroelectric memory capacitors. However, HZO films exhibit fatigue-related degradation during cycling. The present invention aims to address these fatigue issues in HZO materials through the implementation of a doped protective layer.

### First Embodiment

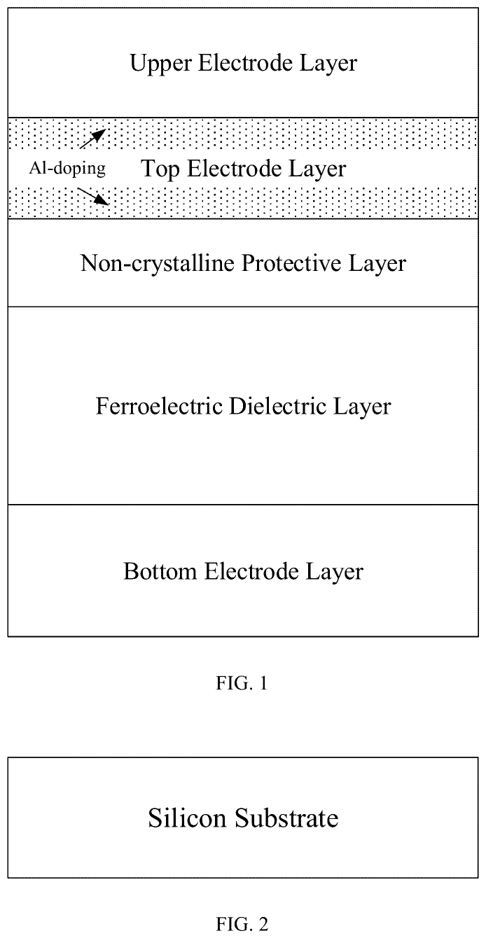

Referring to FIG. 1, a ferroelectric capacitor resisting fatigue is shown as an embodiment. The capacitor includes in sequential order from top to bottom: an upper electrode layer, a top electrode layer, a non-crystalline protective layer, a ferroelectric dielectric layer, and a bottom electrode layer.

Conventional perovskite materials exhibit switching voltages (±0.1 V) incompatible with CMOS logic levels, necessitating impractical voltage scaling for FeFET integration. While the adoption of fluorite-structured hafnium-zirconium-oxygen (HZO) thin films has effectively mitigated this issue, the integration of HZO materials into ferroelectric capacitors introduces a secondary challenge: an elevated coercive field E_{c}. As the coercive field increases to ±0.8-2 V, the fatigue endurance of HZO films is significantly degraded. Consequently, ferroelectric memory devices fabricated with conventional perovskite-based ferroelectric capacitors typically fail after approximately 10¹⁵ polarization switching cycles under operational voltage, whereas devices incorporating HZO-based ferroelectric capacitors experience failure after only ˜10¹⁰ cycles. This insufficient fatigue resistance of HZO films, which results in unacceptably shortened device lifetimes, has emerged as a critical barrier to their industrial-scale commercialization.

The primary failure mechanism of hafnium-zirconium-oxygen (HZO)-based ferroelectric memory devices is attributed to the generation of oxygen vacancies within the dielectric layer during voltage cycling. Prolonged operational cycling leads to excessive oxygen vacancy accumulation, which facilitates the formation of conductive filaments within the thin film. These filaments ultimately coalesce into continuous conductive pathways, resulting in catastrophic device failure. To address this limitation, the present embodiment provides this capacitor.

The ferroelectric dielectric layer consists essentially of a fluorite-structure material selected from the group consisting of ZrO₂, HfO₂ and HfₓZr₁₋ₓO₂. The non-crystalline protective layer includes the same fluorite-structure base material as the ferroelectric dielectric layer and is doped with a predetermined amount of at least one element selected from the group consisting of Al, Si, La, Y, Nb, Ce, and Er, whereby the non-crystalline protective layer attains a non-crystalline state. The non-crystalline protective layer has a thickness ranging from 10% to 40% of a thickness of the ferroelectric dielectric layer. This innovation incorporates a gradient-doped non-crystalline protective layer between the HZO ferroelectric dielectric and the electrode, which suppresses oxygen vacancy migration and mitigates conductive filament nucleation, thereby extending the operational lifetime of the device under high-field cycling conditions.

The newly added non-crystalline protective layer prevents the formation of vertical grain boundaries in conventional ferroelectric capacitors, blocks oxygen vacancy migration, and suppresses conductive filament formation, thereby enhancing fatigue resistance. The non-crystalline protective layer introduces no additional interfaces, maintains stable ferroelectric properties, improves time-dependent dielectric breakdown performance, and reduces leakage current.

The non-crystalline protective layer is formed by atomic layer deposition (ALD), and the dopant material and the ferroelectric dielectric layer material are alternately deposited in a predetermined sequence and ratio to achieve the predetermined thickness of the non-crystalline protective layer. The ferroelectric dielectric layer is formed by ALD and has a thickness of 5 nm. The non-crystalline protective layer is formed by: depositing 2 to 3 cycles of the dopant material directly on an underlying base layer; depositing 8 cycles of the ferroelectric dielectric layer material; and depositing 2 to 3 cycles of the dopant material.

Both the top electrode layer and the bottom electrode layer include TiN and are formed by plasma-enhanced atomic layer deposition (PEALD). The top electrode layer has a thickness of 10 nm to 20 nm, the bottom electrode layer has a thickness of 5 nm to 10 nm. The upper electrode layer includes SiGe and is formed by electron beam evaporation, and the upper electrode layer has a thickness of 270 nm to 300 nm.

This embodiment relates to an improved HZO-based ferroelectric capacitor. The disclosed thin-film structure increases polarization switching cycles in FeFET devices, enhances fatigue characteristics, and ensures reliable data storage. From a manufacturing perspective, the solution requires only minor modifications to dielectric growth processes by adjusting ALD equipment recipes, making it compatible with existing production lines. The ferroelectric memory devices can be manufactured using conventional DRAM production lines without requiring new facility design or process development, enabling easy implementation while reducing production costs.

### Second Embodiment

A ferroelectric storage circuit is shown as an embodiment. The circuit includes a silicon substrate and a circuit structure disposed on the silicon substrate and comprising the capacitor according to the first embodiment.

### Third Embodiment

A ferroelectric storage circuit is shown as an embodiment. The circuit includes a silicon substrate, at least one FeFET, at least one FRAM, and a circuit structure disposed on the silicon substrate and comprising the capacitor according to the first embodiment.

### Fourth Embodiment

Referring to FIGS. 2-11, a ferroelectric memory is shown as an embodiment. The memory includes a large-scale integrated circuit formed by a plurality of unit circuits, each unit circuit being the ferroelectric storage circuit. The memory is fabricated by a method including the sequential steps of (a)-(f).

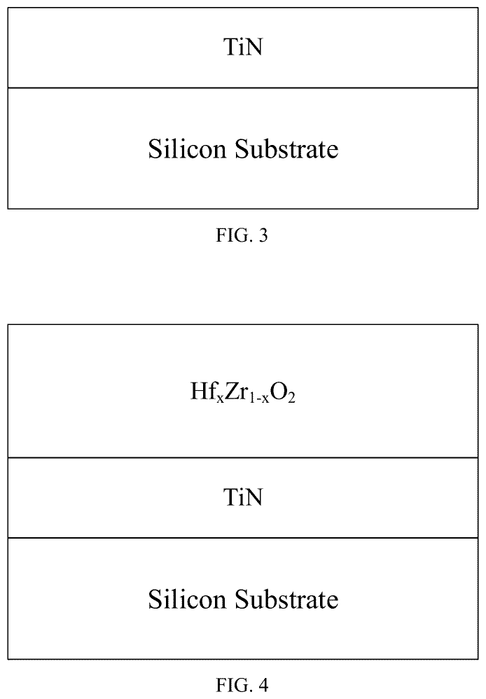

Step (a): providing a silicon substrate (as illustrated in FIG. 2), cleaning a silicon substrate to remove surface contaminants, and depositing a continuous layer of TiN as the bottom electrode on the silicon substrate using PEALD, wherein the bottom electrode has a thickness in the range of 10 nm to 20 nm and fully covers the silicon substrate (as depicted in FIG. 3).

Step (b): forming a continuous film of the ferroelectric dielectric layer on the TiN bottom electrode using ALD, wherein: said ferroelectric dielectric layer is deposited at a growth rate of 0.78 to 1 Å per cycle over 50 to 65 deposition cycles to achieve a final thickness of approximately 5 nm (as shown in FIG. 4). The ferroelectric dielectric layer consists essentially of a fluorite-structure material selected from the group consisting of ZrO2, HfO2 and HfxZr1-xO2. At this point, the ferroelectric dielectric completely covers the bottom electrode.

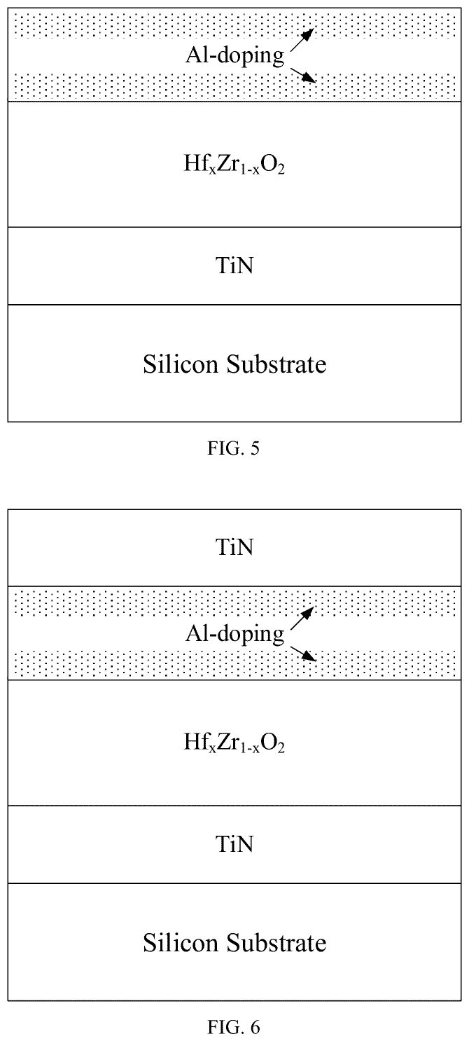

Step (c): depositing 2 to 3 cycles of a dopant material, then 8 cycles of the ferroelectric dielectric layer material, and finally 2 to 3 cycles of the dopant material using ALD to form the non-crystalline protective layer. The non-crystalline protective layer includes the same fluorite-structure base material as the ferroelectric dielectric layer and is doped with a predetermined amount of at least one element selected from the group consisting of Al, Si, La, Y, Nb, Ce, and Er, whereby the non-crystalline protective layer attains a non-crystalline state. The non-crystalline protective layer has a thickness ranging from 10% to 40% of a thickness of the ferroelectric dielectric layer. The non-crystalline protective layer has a thickness of 1 nm to 1.5 nm (as illustrated in FIG. 5).

It is specifically emphasized that during this stage, the dopant material and ferroelectric dielectric material are alternately deposited onto the ferroelectric dielectric thin film. The deposition cycles are intentionally limited in number, resulting in a controlled, insufficient deposition volume of the dopant material to form a continuous, standalone film exclusively comprising the dopant. Consequently, the non-crystalline protective layer formed at this stage includes a composite material wherein dopant atoms are homogeneously distributed and embedded within a matrix of the ferroelectric dielectric base material. Furthermore, in practical fabrication implementations, the sequence and number of deposition cycles may be adjusted to maintain the non-crystalline state of the protective layer and achieve the required thickness.

Step (d): depositing TiN as the top electrode layer on the non-crystalline protective layer using PEALD. The top electrode layer has a thickness of 5-10 nm, is thinner than the bottom electrode layer, and functions to stabilize the crystalline phase of the underlying ferroelectric film (as shown in FIG. 6).

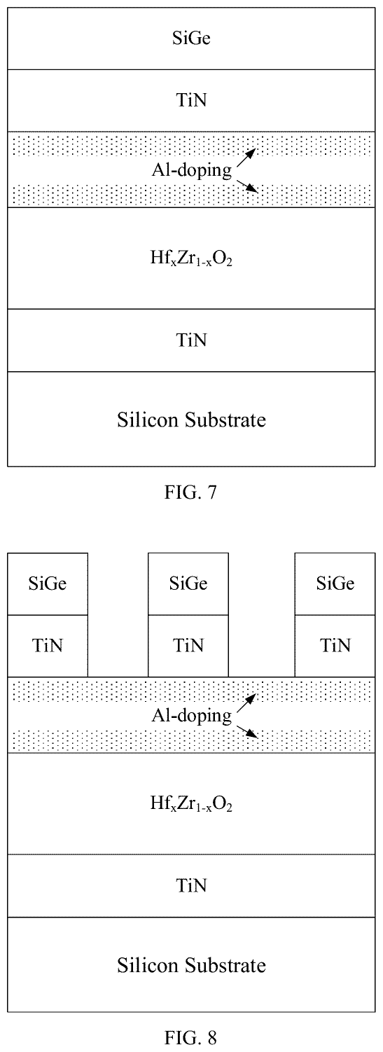

Step (e): depositing a SiGe layer as the upper electrode layer on the top electrode layer using electron beam evaporation (E-beam), wherein the SiGe layer has a thickness of 270 nm to 300 nm (as depicted in FIG. 7).

Step (f): patterning the multilayer structure using photolithography and etching with an inductively coupled plasma etcher to form a metal-ferroelectric-metal (MFM) circuit structure (as illustrated in FIG. 8).

In the ferroelectric memory provided by this embodiment, the insertion of an AZA layer (non-crystalline protective layer comprising doped ferroelectric dielectric material) enables the realization of highly reliable hafnium-zirconium oxide (HZO) material. This configuration achieves three synergistic advantages: (i) no increase in the overall thickness of the HZO thin film; (ii) preservation of the ferroelectric properties of the HZO film with enhanced operational stability, and (iii) elimination of additional interfacial layers between the doped regions and the base ferroelectric matrix, thereby maintaining structural integrity and minimizing parasitic effects.

Furthermore, the ferroelectric memory disclosed herein may be packaged as a commercially viable integrated circuit chip. Accordingly, this embodiment further provides a non-volatile memory chip comprising the aforementioned ferroelectric memory encapsulated within a semiconductor package. The chip retains the functional benefits of the embedded AZA layer, including improved endurance, data retention, and switching uniformity, while meeting industry-standard form factors and reliability requirements for mass-market applications.

### Performance Testing

To validate the advantages of the technical solution disclosed herein, experimental verification was conducted. In the verification tests, 6 nm-thick zirconium oxide (ZrO₂) devices doped with aluminum oxide (experimental group) and undoped ZrO₂ devices (control group) were subjected to high-field cycling at 6 MV/cm. The experimental group included ZAZA (ZrO₂—Al₂O₃—ZrO₂—Al₂O₃) and HZO-AZA (HfₓZr₁₋ₓO₂ with AZA layer) structures, while the control group included pure ZrO₂ devices. The tests aimed to demonstrate the feasibility and superiority of the disclosed solution within HZO-based systems.

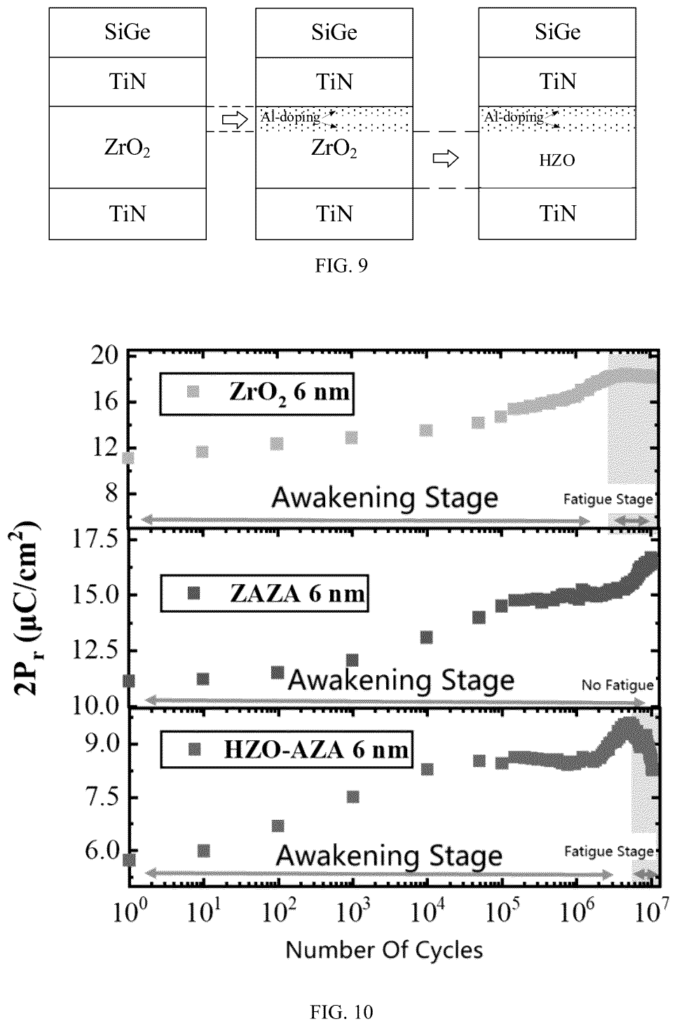

FIG. 9 schematically illustrates the structural comparison between: (i) the control group (undoped ZrO₂ device); (ii) the experimental group with an aluminum-doped protective layer (ZAZA); and (iii) the HZO-AZA device integrating the AZA layer with HZO thin films.

FIG. 10 plots the remnant polarization (Pr) curves derived from experimental data under high-field cycling. The ZAZA thin film in the experimental group exhibits significantly enhanced fatigue resistance. The control group (pure ZrO₂) demonstrates fatigue onset within 10⁷ cycles, whereas the ZAZA structure shows no fatigue trend even at 10⁷ cycles.

The HZO-AZA device exhibits delayed fatigue onset compared to conventional HZO structures. These results conclusively demonstrate that the AZA protective layer, integrated into traditional HZO-based devices, markedly improves operational reliability without compromising ferroelectric performance. Critically, the experimental data confirm that aluminum doping does not degrade ferroelectric properties, as the remnant polarization remains stable at approximately 10 μC/cm². Thus, the disclosed solution achieves superior fatigue resistance while preserving ferroelectric integrity.

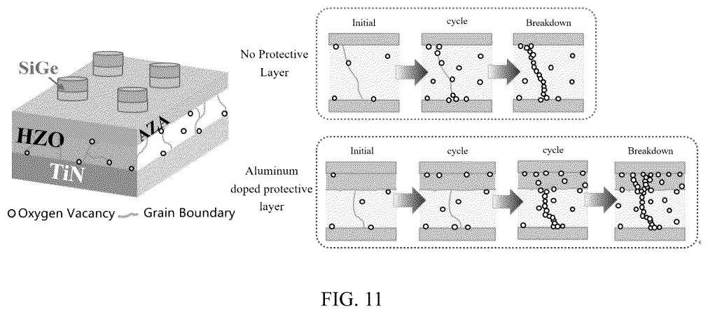

FIG. 11 provides a mechanistic analysis of the performance enhancement. In conventional HZO thin films, high-field cycling-induced failure primarily arises from oxygen vacancy accumulation at grain boundaries, which facilitates conductive filament formation and eventual device degradation. In contrast, the non-crystalline AZA protective layer in the disclosed invention disrupts intergranular connectivity, reduces overall leakage current, and suppresses oxygen vacancy-mediated filament formation. This structural innovation effectively mitigates degradation pathways, thereby enhancing endurance and reliability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A ferroelectric capacitor resisting fatigue comprising, in sequential order from top to bottom:
an upper electrode layer;
a top electrode layer;
a non-crystalline protective layer;
a ferroelectric dielectric layer; and
a bottom electrode layer;
wherein:
(a) the ferroelectric dielectric layer consists essentially of a fluorite-structure material selected from the group consisting of ZrO₂, HfO₂ and HfₓZr₁₋ₓO₂;
(b) the non-crystalline protective layer comprises the same fluorite-structure base material as the ferroelectric dielectric layer and is doped with a predetermined amount of at least one element selected from the group consisting of Al, Si, La, Y, Nb, Ce, and Er, whereby the non-crystalline protective layer attains a non-crystalline state; and
(c) the non-crystalline protective layer has a thickness ranging from 10% to 40% of a thickness of the ferroelectric dielectric layer.

2. The capacitor according to claim 1, wherein the non-crystalline protective layer is formed by atomic layer deposition (ALD), and the dopant material and the ferroelectric dielectric layer material are alternately deposited in a predetermined sequence and ratio to achieve the predetermined thickness of the non-crystalline protective layer.

3. The capacitor according to claim 2, wherein the non-crystalline protective layer is formed by:
depositing 2 to 3 cycles of the dopant material directly on an underlying base layer;
depositing 8 cycles of the ferroelectric dielectric layer material; and
depositing 2 to 3 cycles of the dopant material.

4. The capacitor according to claim 1, wherein both the top electrode layer and the bottom electrode layer comprise TiN and are formed by plasma-enhanced atomic layer deposition (PEALD).

5. The capacitor according to claim 1, wherein the top electrode layer has a thickness of 10 nm to 20 nm, the bottom electrode layer has a thickness of 5 nm to 10 nm.

6. The capacitor according to claim 1, wherein the upper electrode layer comprises SiGe and is formed by electron beam evaporation, and the upper electrode layer has a thickness of 270 nm to 300 nm.

7. The capacitor according to claim 1, wherein the ferroelectric dielectric layer is formed by ALD and has a thickness of 5 nm.

8. A ferroelectric storage circuit comprising:
a silicon substrate; and
a circuit structure disposed on the silicon substrate and comprising the capacitor according to claim 1.

9. The circuit according to claim 8, wherein further comprising:
at least one ferroelectric field-effect transistor (FeFET); and
at least one ferroelectric random-access memory (FRAM).

10. The circuit according to claim 8, wherein the non-crystalline protective layer is formed by ALD, and the dopant material and the ferroelectric dielectric layer material are alternately deposited in a predetermined sequence and ratio to achieve the predetermined thickness of the non-crystalline protective layer.

11. The circuit according to claim 10, wherein the non-crystalline protective layer is formed by:
depositing 2 to 3 cycles of the dopant material directly on an underlying base layer;
depositing 8 cycles of the ferroelectric dielectric layer material; and
depositing 2 to 3 cycles of the dopant material.

12. The circuit according to claim 8, wherein both the top electrode layer and the bottom electrode layer comprise TiN and are formed by PEALD.

13. The circuit according to claim 8, wherein the top electrode layer has a thickness of 10 nm to 20 nm, the bottom electrode layer has a thickness of 5 nm to 10 nm.

14. The circuit according to claim 8, wherein the upper electrode layer comprises SiGe and is formed by electron beam evaporation, and the upper electrode layer has a thickness of 270 nm to 300 nm.

15. The circuit according to claim 8, wherein the ferroelectric dielectric layer is formed by ALD and has a thickness of 5 nm.

16. A ferroelectric memory comprising:
a large-scale integrated circuit formed by a plurality of unit circuits, each unit circuit being the ferroelectric storage circuit according to claim 8.

17. The memory according to claim 16, wherein the memory is fabricated by a method comprising:
(a) cleaning a silicon substrate and depositing a continuous layer of TiN as the bottom electrode on the silicon substrate using PEALD;
(b) forming a continuous film of the ferroelectric dielectric layer on the TiN bottom electrode using ALD;
(c) depositing 2 to 3 cycles of a dopant material, then 8 cycles of the ferroelectric dielectric layer material, and finally 2 to 3 cycles of the dopant material using ALD to form the non-crystalline protective layer;
(d) depositing TiN as the top electrode layer on the non-crystalline protective layer using PEALD;
(e) depositing a SiGe layer as the upper electrode layer on the top electrode layer using electron beam evaporation; and
(f) patterning the multilayer structure using photolithography and etching with an inductively coupled plasma etcher to form a metal-ferroelectric-metal (MFM) circuit structure.

18. The memory according to claim 16, wherein the non-crystalline protective layer is formed by ALD, and the dopant material and the ferroelectric dielectric layer material are alternately deposited in a predetermined sequence and ratio to achieve the predetermined thickness of the non-crystalline protective layer.

19. The memory according to claim 18, wherein the non-crystalline protective layer is formed by:
depositing 2 to 3 cycles of the dopant material directly on an underlying base layer;
depositing 8 cycles of the ferroelectric dielectric layer material; and
depositing 2 to 3 cycles of the dopant material.

20. The memory according to claim 16, wherein:
(a) both the top electrode layer and the bottom electrode layer comprise TiN and are formed by PEALD;
(b) the top electrode layer has a thickness of 10 nm to 20 nm, the bottom electrode layer has a thickness of 5 nm to 10 nm;
(c) the upper electrode layer comprises SiGe and is formed by electron beam evaporation, and the upper electrode layer has a thickness of 270 nm to 300 nm;
(d) the ferroelectric dielectric layer is formed by ALD and has a thickness of 5 nm.
